(19) United States
(12) Patent Application Publication
(10) Pub. No.: US 2020/0152487 A1
(43) Pub. Date: May 14, 2020

(54) METHOD OF CLEANING A SEMICONDUCTOR CHIP AND APPARATUS FOR PERFORMING THE SAME

(71) Applicant: SAMSUNG ELECTRONICS CO., LTD., Suwon-si (KR)

(72) Inventors: Hye-Kyoung LEE, Suwon-si (KR); Sung-Hyeon PARK, Asan-si (KR)

(21) Appl. No.: 16/420,359

(22) Filed: May 23, 2019

(30) Foreign Application Priority Data
Nov. 8, 2018 (KR) 10-2018-0136259

(51) Int. Cl. H01L 21/67; H01L 21/02; B08B 3/08; F26B 5/08

(52) U.S. Cl. CPC H01L 21/67051; H01L 21/67034; F26B 5/08; B08B 3/08; H01L 21/02068

(57) ABSTRACT

A method of and apparatus for cleaning a semiconductor chip, the method including applying a first polar composition to a protection layer on a surface of at least one semiconductor chip to remove a particle from the surface of the at least one semiconductor chip and suspend the particle in the first polar composition; and applying a second polar composition, having a surface tension that is lower than that of the first polar composition, to a central portion of the applied first polar composition to push the first polar composition and the particle toward an outskirt of the at least one semiconductor chip.

### CROSS-REFERENCE TO RELATED APPLICATION

Korean Patent Application No. 10-2018-0136259, filed on Nov. 8, 2018, in the Korean Intellectual Property Office, and entitled: “Method of Cleaning a Semiconductor Chip and Apparatus for Performing the Same,” is incorporated by reference herein in its entirety.

### BACKGROUND

### 1. Field

Embodiments relate to a method of cleaning a semiconductor chip and an apparatus for performing the same.

### 2. Description of the Related Art

A plurality of CMOS image sensors may be formed on a semiconductor substrate. The semiconductor substrate may be cut along scribe lanes to singulate or separate the CMOS image sensors.

### SUMMARY

The embodiments may be realized by providing a method of cleaning a semiconductor chip, the method including applying a first polar composition to a protection layer on a surface of at least one semiconductor chip to remove a particle from the surface of the at least one semiconductor chip and suspend the particle in the first polar composition; and applying a second polar composition, having a surface tension that may be lower than that of the first polar composition, to a central portion of the applied first polar composition to push the first polar composition and the particle toward an outskirt of the at least one semiconductor chip.

The embodiments may be realized by providing a method of cleaning a CMOS image sensor, the method including dissolving an acryl polymer layer on a surface of at least one CMOS image sensor by applying a first polar composition thereto such that a particle may be removed from the surface of the at least one CMOS image sensor and suspended in the first polar composition; applying a second polar composition, having a surface tension that may be lower than that of the first polar composition, to a central portion of the applied first polar composition to push the first polar composition and the particle toward an outskirt of the at least one CMOS image sensor; injecting deionized water to the at least one CMOS image sensor; and drying the deionized water from the surface of the at least one CMOS image sensor.

The embodiments may be realized by providing an apparatus for cleaning a semiconductor chip that includes a protection layer on a surface thereof, the apparatus including a first nozzle arranged to be over the protection layer on a surface of the semiconductor chip and to apply a first polar composition to the protection layer to remove a particle from the surface of the semiconductor chip and suspend the particle in the first polar composition; and a second nozzle arranged to be over the protection layer and to apply a second polar composition, having a surface tension that may be lower than that of the first polar composition, to a central portion of the applied first polar composition to push the first polar composition and the particle toward an outskirt of the semiconductor chip.

### BRIEF DESCRIPTION OF THE DRAWINGS

Features will be apparent to those of skill in the art by describing in detail exemplary embodiments with reference to the attached drawings in which:

FIGS. 1 to 6 illustrate cross-sectional views of stages in a method of cleaning a semiconductor chip using a cleaning apparatus in accordance with example embodiments; and

FIG. 7 illustrates a flow chart of a method of cleaning a semiconductor chip in accordance with example embodiments.

### DETAILED DESCRIPTION

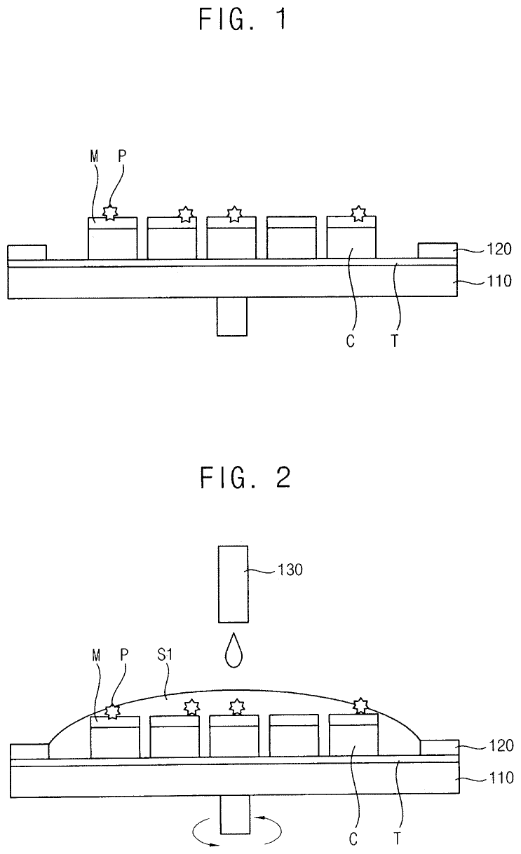

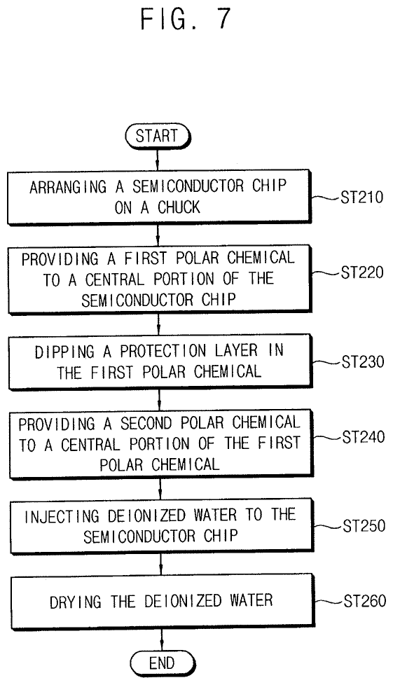

FIGS. 1 to 6 illustrate cross-sectional views of stages in a method of cleaning a semiconductor chip using a cleaning apparatus in accordance with example embodiments, and FIG. 7 illustrates a flow chart of a method of cleaning a semiconductor chip in accordance with example embodiments.

Referring to FIGS. 1 and 7, in operation ST210, semiconductor chips C may be arranged on an upper surface of a chuck 110. In an implementation, a tape T (to which the semiconductor chips C may be attached) may be arranged on the upper surface of the chuck 110. The semiconductor chips C may be formed by cutting a semiconductor substrate. The semiconductor chip C may include a CMOS image sensor.

A protection layer M may be formed on an upper surface of each of the semiconductor chips C. The protection layer M may help prevent particles P, which may be generated in the cutting process of the semiconductor substrate, from being attached to the semiconductor chip C. For example, the particles P may instead be attached to a surface of the protection layer M. In an implementation, the protection layer M may include an acryl polymer.

In an implementation, the chuck 110 may include a spin chuck that may rotate (e.g., the tape T) with respect to a vertical axis. The tape T may be fixed in place with a ring 120 at an edge portion of the upper surface of the chuck 110.

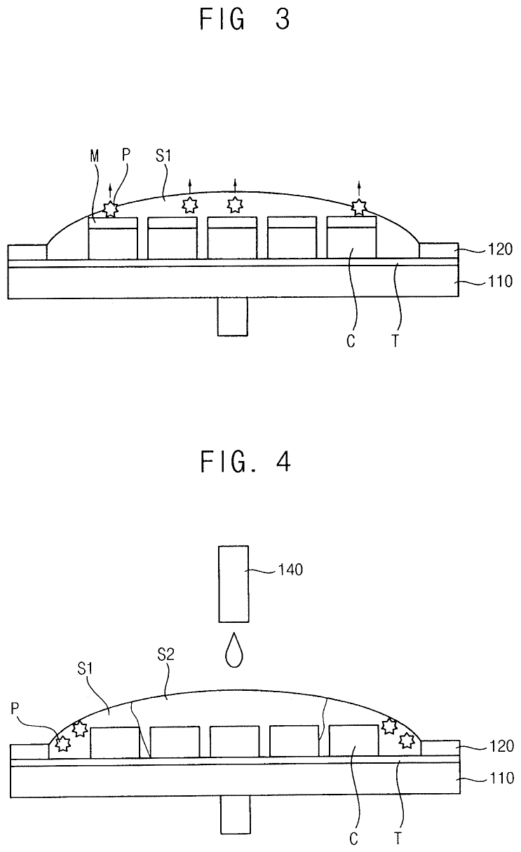

Referring to FIGS. 2 and 7, in operation ST220, a first nozzle 130 may be arranged over the semiconductor chips C. The first nozzle 130 may inject a first polar composition S1 (e.g., first polar chemical) to a central portion of the chuck 110 and onto protection layer M. In an implementation, the first nozzle 130 may inject a first composition to a central portion of the chuck 110 or the semiconductor chip(s) C.

The first polar composition S1 may dissolve the protection layer M. The protection layer M may include the acryl polymer, and the first polar composition S1 may include a material for dissolving the acryl polymer. In an implementation, the first polar composition S1 may include a material for preventing a deformation of the tape T (with the semiconductor chips C thereon). In an implementation, the first polar composition S1 may include a material for preventing corrosion of the ring 120 (that fixes the position of the tape T). For example, the first polar composition S1 may include a material for preventing damage to active pixel and pads of the semiconductor chips C. In an implementation, the first polar composition S1 may include, e.g., dimethyl sulfoxide (DMSO), glycol, and amine. In an implementation, the first polar composition S1 may include about 70% to about 90% by weight of the DMSO, about 1% to about 15% by weight of the glycol, and about 1% to about 15% by weight of the amine (e.g., based on a total weight of the first polar composition S1).

In an implementation, the first polar composition S1 may be supplied to the surface of the protection layer M through the first nozzle 130 in an amount sufficient for covering the entire surface of the protection layer M (e.g., on all of the semiconductor chips C). In an implementation, the supplied amount of the first polar composition S1 (e.g., for covering the entire surface of the protection layer M) may be, e.g., about 50 ml to about 250 ml. The supplied amount of the first polar composition S1 may be selected in accordance with a thickness of the protection layer M to be dissolved by the first polar composition S1. In an implementation, in order to cover the entire surface of the protection layer M with the first polar composition S1, the first polar composition S1 may be supplied to the protection layer M as the semiconductor chips C are rotated by the chuck 110.

Referring to FIGS. 3 and 7, in operation ST230, the protection layer M may be dipped in, covered, or otherwise exposed to the first polar composition S1 until the protection layer M is dissolved. The particles P on the surface of the protection layer M may float or be suspended in the first polar composition S1 (e.g., or otherwise be drawn away from the surfaces of the semiconductor chips C) by dissolving the protection layer M. In an implementation, the protection layer M may be exposed to the first polar composition S1 for, e.g., about 10 seconds to about 300 seconds. The exposure time of the protection layer M to the first polar composition S1 may be selected in accordance with the thickness of the protection layer M (e.g., a thicker protection layer M may be exposed to the first polar composition S1 for a longer time).

Referring to FIGS. 4 and 7, in operation ST240, a second nozzle 140 may be arranged over the semiconductor chips C. The second nozzle 140 may inject a second polar composition S2 (e.g., second polar chemical) to a central portion of the applied first polar composition S1 (e.g., to a central portion of the chuck 110 accommodating the semiconductor chips C thereon).

In an implementation, the second polar composition S2 may have a surface tension that is lower than that of the first polar composition S1. For example, the second polar composition S2 may be applied to the central portion of the first polar composition S1 (already having been applied to the semiconductor chips C), and the first polar composition S1 may be pushed outwardly toward an outskirt or outer edge of the semiconductor chip C or chuck 110, e.g., an outer edge portion of the tape T, due to a difference between the surface tensions of the first and second polar compositions S1 and S2. For example, the particles P suspended in the first polar composition S1 may also be pushed outwardly toward the outskirt of the semiconductor chip C or chuck 110 together with the first polar composition S1. In an implementation, the surface tension of the second polar composition S1 may be, e.g., about 10% to about 60% of the surface tension of the first polar composition S1.

If a second composition applied to the central portion of the first polar composition S1 were to not have a polarity, non-polar components in the second composition may have strong coherence. The strong coherence in the second composition could weaken a pushing force to polar components in the first polar composition S1 toward the outskirt of the semiconductor chip C or chuck 110. For example, the second polar composition S2 of an embodiment may have the polarity for strongly pushing the polar components in the first polar composition S1 toward the outskirt of the semiconductor chip C or chuck 110. In an implementation, the second polar composition S2 may include, e.g., methanol, ethanol, propanol (e.g., isopropanol IPA), n-hexane, n-octane, perfluorohexane, perfluorootane, chloro butane, acetone, chloroform, isobutylchloride, a combination thereof, or the like.

A supplied amount of the second polar composition S2 may be no more than (e.g., less than or equal to) the supplied amount of the first polar composition S1. For example, the supplied amount of the second polar composition S2 may be about 50% to about 100% of the supplied amount of the first polar composition S1.

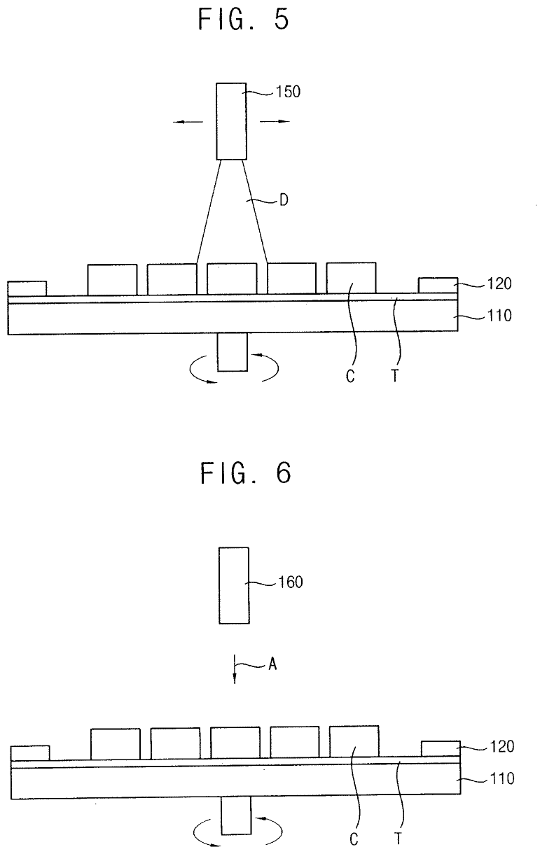

Referring to FIGS. 5 and 7, in operation ST250, a third nozzle 150 may be arranged over the semiconductor chips C. The third nozzle 150 may inject deionized water D to the semiconductor chips C to clean the semiconductor chips C. The third nozzle 150 may inject the deionized water D to the semiconductor chips C as the semiconductor chips C are rotated by the chuck 110. The third nozzle 150 may inject the deionized water D to the semiconductor chip C with the third nozzle 150 being horizontally moved.

In an implementation, the deionized water D may have an injection pressure that is selected with a view toward preventing the semiconductor chips C from being detached from the tape T. For example, the injection pressure of the deionized water D may be about 0.05 MPa to about 1.0 MPa. In an implementation, the rotation speed of the chuck 110 may be about 100 rpm to about 1,000 rpm.

Referring to FIGS. 6 and 7, in operation ST260, a fourth nozzle 160 may be arranged over the semiconductor chips C. The fourth nozzle 160 may inject dry air A to the semiconductor chips C to dry the deionized water D on the semiconductor chips C. The fourth nozzle 160 may inject the dry air A to the semiconductor chips C as the semiconductor chips C are rotated by the chuck 110. In an implementation, the chuck 120 may be, e.g., rotated at a speed of no less than (e.g., greater than or equal to) about 1,000 rpm for no less than (e.g., greater than or equal to) about two minutes.

By way of summation and review, particles generated in the cutting process may smear or otherwise remain on the CMOS image sensors, and errors of the CMOS image sensors could be generated. In order to help prevent the CMOS image sensors from being smeared or covered with the particles, a protection layer may be formed on the CMOS image sensors.

Deionized water could be injected on or provided to the CMOS image sensor to remove the particles. Particles on an uneven surface of the CMOS image sensor may not be easily removed using the deionized water. A process for removing the protection layer from the CMOS image sensor may be performed.

One or more embodiments may provide a method of removing particles from a CMOS image sensor.

In example embodiments, the cleaning method may be applied to the CMOS image sensor with the protection layer. Alternatively, the cleaning method of example embodiments may be applied other semiconductor chips with the protection layer.

One or more embodiments may provide a method of cleaning a semiconductor chip that may be capable of effectively removing particles and a protection layer.

According to example embodiments, the first polar composition may dissolve the protection layer to remove the particle from the surface of the semiconductor chip and be floated or suspended in the composition. When the second polar composition is applied to the central portion of the first polar composition, the first polar composition and the particle may be pushed toward the outskirt of the semiconductor chip due to a difference between the surface tensions of the first and second polar compositions. Thus, the particle may be effectively removed from the semiconductor chip simultaneously with removing the protection layer.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A method of cleaning a semiconductor chip, the method comprising:
applying a first polar composition to a protection layer on a surface of at least one semiconductor chip to remove a particle from the surface of the at least one semiconductor chip and suspend the particle in the first polar composition; and
applying a second polar composition, having a surface tension that is lower than that of the first polar composition, to a central portion of the applied first polar composition to push the first polar composition and the particle toward an outskirt of the at least one semiconductor chip.

2. The method as claimed in claim 1, wherein applying the first polar composition to the protection layer includes dissolving the protection layer in the first polar composition to remove the particle from the surface of the at least one semiconductor chip and suspend the particle in the first polar composition.

3. The method as claimed in claim 2, wherein applying the first polar composition to the protection layer includes exposing the protection layer with the first polar composition until the protection layer is dissolved.

4. The method as claimed in claim 3, wherein the protection layer is exposed to the first polar composition for about 10 seconds to about 300 seconds.

5. The method as claimed in claim 2, wherein:
the protection layer includes an acryl polymer, and
the first polar composition includes dimethyl sulfoxide, a glycol, and an amine.

6. The method as claimed in claim 5, wherein the first polar composition includes about 70% to about 90% by weight of the DMSO, about 1% to about 15% by weight of the glycol, and about 1% to about 15% by weight of the amine.

7. The method as claimed in claim 1, wherein applying the first polar composition to the protection layer includes providing the first polar composition to a central portion of the protection layer to cover an entire surface of the protection layer with the first polar composition.

8. The method as claimed in claim 7, wherein an amount of the first polar composition applied to the surface of the protection layer is about 50 ml to about 250 ml.

9. The method as claimed in claim 7, wherein applying the first polar composition to the protection layer includes providing the first polar composition to the protection layer as the at least one semiconductor chip is rotated.

10. The method as claimed in claim 1, wherein the surface tension of the second polar composition is about 10% to about 60% of the surface tension of the first polar composition.

11. The method as claimed in claim 10, wherein the second polar composition includes methanol, ethanol, propanol, n-hexane, n-octane, perfluorohexane, perfluorooctane, chlorobutane, acetone, chloroform, isobutylchloride, or a combination thereof.

12. The method as claimed in claim 1, wherein a provided amount of the second polar composition is less than or equal to a provided amount of the first polar composition.

13. The method as claimed in claim 1, further comprising injecting deionized water to the at least one semiconductor chip after applying the second polar composition to the first polar composition.

14. The method as claimed in claim 13, wherein an injection pressure of the deionized water is about 0.05 MPa to about 1.0 MPa.

15. The method as claimed in claim 13, wherein injecting the deionized water to the at least one semiconductor chip includes rotating the semiconductor chip.

16. The method as claimed in claim 15, wherein the at least one semiconductor chip is rotated at a speed of about 100 rpm to about 1,000 rpm.

17. The method as claimed in claim 13, further comprising drying the deionized water from the surface of the at least one semiconductor chip.

18. The method as claimed in claim 17, wherein drying the deionized water includes rotating the at least one semiconductor chip.

19. The method as claimed in claim 18, wherein the at least one semiconductor chip is rotated at a speed of greater than or equal to about 1,000 rpm for greater than or equal to about two minutes.

20. The method as claimed in claim 1, wherein the at least one semiconductor chip includes a CMOS image sensor.

21.-38. (canceled)
